(19) United States
(12) Patent Application Publication
(10) Pub. No.: US 2026/0161860 A1
(43) Pub. Date: Jun. 11, 2026

(54) METHOD FOR RAPIDLY EVALUATING FLOOD DRAINAGE EFFECT BASED ON MACHINE LEARNING AND ENSEMBLE PREDICTION

(71) Applicants: Jiangsu Second Normal University, Nanjing (CN); Hebei Meteorological Disaster Prevention and Environmental Meteorological Center, Shijiazhuang (CN); Nanjing University of Information Science & Technology, Jiangsu (CN)

(72) Inventors: Tong Jiang, Nanjing (CN); Lili Si, Shijiazhuang (CN); Yun Xing, Nanjing (CN); Buda Su, Nanjing (CN); Yanjun Wang, Nanjing (CN); Jinlong Huang, Nanjing (CN); Qigen Lin, Nanjing (CN); Shan Jiang, Nanjing (CN); Cheng Jing, Nanjing (CN); Xikun Wei, Nanjing (CN)

(21) Appl. No.: 19/328,261

(22) Filed: Sep. 15, 2025

(30) Foreign Application Priority Data
Dec. 10, 2024 (CN) 202411808187.8

(51) Int. Cl. G06F 30/28; G06F 30/27; G06N 20/20

(52) U.S. Cl. CPC G06F 30/28; G06F 30/27; G06N 20/20

(57) ABSTRACT

A method for rapidly evaluating flood drainage effect based on machine learning and ensemble prediction is provided, including the following steps: S1, collecting and organizing feature data for predicting and evaluating the flood drainage effect; S2, constructing a flood hydrodynamic numerical model based on a physical mechanism; S3, constructing a data set, and pre-processing the data set; S4, determining a target hyperparameter combination of each of multiple machine learning regression models by using a Bayesian optimizer; S5, training multiple machine learning regression models based on multiple machine learning methods and hyperparameter optimization; S6, performing ensemble prediction on each machine learning regression model to construct a prediction and evaluation model of the flood drainage effect; and S7, using the prediction and evaluation model of the step S6 to rapidly evaluate and predict the flood drainage effect. The method improves a response speed of urban flood emergency management.

### CROSS-REFERENCE TO RELATED APPLICATION

This application claims priority to Chinese Patent Application No. 202411808187.8, filed on Dec. 10, 2024, which is herein incorporated by reference in its entirety.

### TECHNICAL FIELD

The disclosure relates to the technical field of flood numerical forecasting, and more particularly to a method for rapidly evaluating flood drainage effect based on machine learning and ensemble prediction.

### BACKGROUND

Urban flooding will become more frequent due to an increase in a frequency of extreme rainfall caused by climate change. A dynamic process of the urban flooding is closely related to an urban surface and drainage conditions. Describing a flood process through drainage systems and complex urban environments is essential for understanding and evaluating urban flood risks.

Existing hydrodynamic numerical models can simulate an evolution process of the urban flooding under a drainage effect of pipe network, but timeliness of rapid response decision-making required for urban flood emergency management is still insufficient. At present, the widely used machine learning has a certain degree of efficiency, but a single regression model based on machine learning cannot accurately and effectively predict.

### SUMMARY

An objective of the disclosure is to provide a method for rapidly evaluating flood drainage effect based on machine learning and ensemble prediction, which combines with a hydrodynamic numerical model with physical significance, uses multiple regression algorithms based on machine learning methods, and performs ensemble prediction through Bayesian hyperparameter optimization to solve problems existed in the background technology.

A technical solution of the disclosure is a method for rapidly evaluating flood drainage effect based on machine learning and ensemble prediction, including the following steps:
S1, collecting and organizing feature data for predicting and evaluating the flood drainage effect;
S2, constructing a flood hydrodynamic numerical model based on a physical mechanism;
S3, constructing a data set, and pre-processing the data set;
S4, determining an optimal hyperparameter combination (i.e., target hyperparameter combination) of each of multiple machine learning regression models by using a Bayesian optimizer;
S5, training the multiple machine learning regression model based on multiple machine learning methods and hyperparameter optimization;
S6, performing ensemble prediction on each machine learning regression model to construct a prediction and evaluation model of the flood drainage effect; and
S7, using the prediction and evaluation model of the step (6) to rapidly evaluate and predict the flood drainage effect.

In an embodiment, the S1 specifically includes: collecting relevant terrain data and rainfall data to drive simulation and calculation of a hydrodynamic model. The relevant terrain data includes: terrain elevation data, and different slope data, the rainfall data is rainfall data of different rainfall intensities and different rainfall durations.

In an embodiment, the S2 includes:
calculating the flood hydrodynamic numerical model by using a two-dimensional shallow water equation, where a control equation of the two-dimensional shallow water equation is expressed as follows:

$$\frac{\partial q}{\partial t} + \frac{\partial f}{\partial x} + \frac{\partial g}{\partial y} = R + {S}_{b} + {S}_{f} ;$$

where t represents a time variable, x and y represent a Cartesian coordinate in horizontal and vertical directions, q represents a vector of each of hydraulic variables, f and g represent fluxes in an x direction and a y direction, respectively, R represents a mass term, S_{b} represents a bed slope, and S_{f} represents a bed friction term; and formulas of q, f, g, R, S_{b} and S_{f} are as follows:

$$q = {[ h , uh , vh ]}^{T} , f = {[ uh , {u}^{2} h + \frac{1}{2} {gh}^{2} , uvh ]}^{T} , g = {[ vh , uvh , {v}^{2} h + \frac{1}{2} {gh}^{2} ]}^{T}$$

$$R = {[ R - I - D , 0 , 0 ]}^{T} , {S}_{b} = {[ 0 , - gh \frac{\partial b}{\partial x} , - gh \frac{\partial b}{\partial y} ]}^{T} ,$$

$${S}_{f} = {[ 0 , - {C}_{f} u \sqrt{{u}^{2} + {v}^{2}} , - {C}_{f} v \sqrt{{u}^{2} + {v}^{2}} ]}^{T} ;$$

where h represents a surface-water depth, u represents an average velocity component corresponding to the x direction, v represents an average velocity component corresponding to the y direction, b represents a bed elevation, g represents a gravitational acceleration, R represents a rainfall rate, I represents a penetration rate, D represents a drainage loss, and C_{f} represents a bed friction coefficient; and
performing spatial discretization on the control equation by using a finite volume method in a Godunov format; calculating an interface flux by using a Harten-Lax-van Leer-contact (HLLC) Riemann solver, and performing time discretization on the control equation by using an explicit method, where a time step is determined according to a Courant-Friedrichs-Lewy (CFL) condition.

In an embodiment, the S3 specifically includes:
defining a normalized predicted value index R_{DE}, wherein a formula of the normalized predicted value index R_{DE} is expressed as follows:

$${R}_{DE} = \frac{{A}_{noDL \vert {h}^{*}} - {A}_{DL \vert {h}^{*}}}{{N}_{inlet} \times {A}_{noDL \vert {h}^{*}}} ;$$

where A_{noDL} represents a flood inundation area without considering drainage under a water depth threshold h* that affects a normal operation of pedestrians and vehicles in a city, and A_{DL} represents a flood inundation area considering the drainage under the water depth threshold h* that affects the normal operation of the pedestrians and vehicles in the city; and Nᵢₙₗₑₜ represents a total number of rainwater outlets in the selected research area;
taking different parameter combinations as input parameters of the flood hydrodynamic numerical model, and calculating, based on the flood hydrodynamic numerical model, the drainage effect index R_{DE} driven by each of the different parameter combinations to construct the data set; and
dividing the data set into a training set and a testing set, and performing normalization preprocessing on the training set and the testing set.

In an embodiment, the S4 specifically includes:
constructing, by using multiple machine learning methods and combining the Bayesian optimizer, the multiple machine learning regression models to predict and evaluate the flood drainage effect of urbans; where the multiple machine learning regression models include: an extreme gradient boosting (XGBoost) model, a Random Forest model, a light gradient boosting machine (LightGBM) model, an extremely randomized tree (Extra Trees) model, and an elastic network (Elastic Net) model;
for each machine learning regression model, initializing hyperparameters to determine a value range of each of the hyperparameters, and determining an optimal value (i.e., target value) of each of the hyperparameters by combining the Bayesian optimizer, where the hyperparameters include: a number of trees (n_estimators), a maximum depth (max_depth) and a learning rate (learning_rate).

In an embodiment, the S5 specifically includes:
training each machine learning regression model after determining the optimal hyperparameter combination for each machine learning regression model, including:
   training the XGBoost model to obtain a final predicted value of the XGBoost model for input data;
   training the Random Forest model to obtain a final predicted value of the Random Forest model for the input data;
   training, by weighting predictive results of all trees, the LightGBM model to obtain a final predicted value of the LightGBM model for the input data;
   training the Extra Trees model to obtain a final predicted value of input data of the Extra Trees model; and
   training the Elastic Net model to obtain an optimal parameter configuration (i.e., target parameter configuration) of the Elastic Net model to thereby obtain a final predicted value of the Elastic Net model for the input data.

In an embodiment, the S6 specifically includes:
recording a feature matrix containing predictive results of the plurality of machine learning regression models formed by the final predicted value of the XGBoost model, the final predicted value of the Random Forest model, the final predicted value of the LightGBM model, the final predicted value of the Extra Trees model and the final predicted value of the Elastic Net model for the input data as X_{ensemble}, where the feature matrix X_{ensemble} is expressed as follows:

$${X}_{ensemble} = [ {\hat{Y}}_{XGBoost} , {\hat{Y}}_{RandomForest} , {\hat{Y}}_{LightGBM} , {\hat{Y}}_{ExtraTrees} , {\hat{Y}}_{ElasticNet} ] ;$$

where Ŷ_{XGBoost} represents the final predicted value of the XGBoost model for the input data, Ŷ_{RandomForest} represents the final predicted value of the Random Forest model for the input data, Ŷ_{LightGBM} represents the final predicted value of the LightGBM model for the input data, Ŷ_{ExtraTrees} represents the final predicted value of the Extra Trees model for the input data, and Ŷ_{ElasticNet} represents the final predicted value of the Elastic Net model for the input data;
assigning, by using a linear weighted integration method, weights to the final predicted value of the XGBoost model, the final predicted value of the Random Forest model, the final predicted value of the LightGBM model, the final predicted value of the Extra Trees model and the final predicted value of the Elastic Net model to perform weighted sum, to thereby a final ensemble prediction value, including:
   determining an optimal weight (i.e., target weight) of each of the XGBoost model, the Random Forest model, the LightGBM model, the Extra Trees model and the Elastic Net model by using a least squares method;
   performing, by using the optimal weight of each of the XGBoost model, the Random Forest model, the LightGBM model, the Extra Trees model and the Elastic Net model, the weighted sum on the final predicted value of the XGBoost model, the final predicted value of the Random Forest model, the final predicted value of the LightGBM model, the final predicted value of the Extra Trees model and the final predicted value of the Elastic Net model to obtain the final ensemble prediction value and the prediction and evaluation model; and
   evaluating the prediction and evaluation model by using a mean square error and a R-squared (R²) score after completing the ensemble prediction.

In an embodiment, the determining an optimal weight of each of the XGBoost model, the Random Forest model, the LightGBM model, the Extra Trees model and the Elastic Net model by using a least squares method includes:
assuming a weight vector as w=[w_{XGBoost}, w_{RandomForest}, w_{LightGBM}, w_{ExtraTrees}, w_{ElasticNet}], where w_{XGBoost} represents a weight of the XGBoost model, w_{RandomForest} represents a weight of the Random Forest model, w_{LightGBM} represents a weight of the LightGBM model, w_{ExtraTrees} represents a weight of the Extra Trees model, and w_{ElasticNet} represents a weight of the Elastic Net model; and a final predicted value Ŷ_{ensemble} of each of testing samples is expressed as follows:

$${\hat{Y}}_{ensemble} = {w}_{XGBoost} \cdot {\hat{Y}}_{XGBoost} + {w}_{RandomForest} \cdot {\hat{Y}}_{RandomForest} + {w}_{LightGBM} \cdot {\hat{Y}}_{LightGBM} + {w}_{ExtraTrees} \cdot {\hat{Y}}_{ExtraTrees} + {w}_{ElasticNet} \cdot {\hat{Y}}_{ElasticNet} ;$$

determining a weight vector w* through a minimum loss function and using the feature matrix X_{ensemble} and an actual observation value vector Yₜₑₛₜ of each of the testing samples, where a formula of the minimize loss function is expressed as follows:

$${{min}_{w} ( {X}_{ensemble} \cdot w - {Y}_{test} )}^{2} .$$

In an embodiment, the method further includes:
inputting feature data of a target area under different layouts of rainwater outlets into the prediction and evaluation model of the flood drainage effect to obtain a final ensemble prediction value for each of the different layouts of the rainwater outlets;
comparing the final ensemble prediction value for each of the different layouts of the rainwater outlets to obtain a maximum ensemble prediction value of the different layouts of the rainwater outlets; and
selecting a layout of the rainwater outlets with the maximum ensemble prediction value from the different layouts of the rainwater outlets as a target layout of the rainwater outlets to perform municipal planning in the target area, thereby reducing a risk of flood disasters.

The disclosure provides an electronic device, including a memory, a processor and a computer program stored on the memory and executed on the processor, and the computer program is configured to be loaded on the processor to implement the method for rapidly evaluating the flood drainage effect based on machine learning and ensemble prediction.

The disclosure provides a non-transitory storage medium, the non-transitory storage medium is stored with a computer program, and the computer program is configured to be executed by the processor to implement the method for rapidly evaluating the flood drainage effect based on machine learning and ensemble prediction.

Compared with the related art, the disclosure has the following significant advantages. The disclosure combines the hydrodynamic numerical model and the multi-regression model ensemble prediction method based on Bayesian optimization, which greatly improves the response speed of urban flood emergency management. In extreme rainfall events, the drainage effect of different rainwater outlets in urban floods can be quickly evaluated, so that relevant emergency departments can make decisions more quickly, deploy rescue resources, and reduce potential property losses and casualties. By predicting and evaluating the drainage effects under various rainwater outlet layout schemes, a scientific basis can be provided for urban planning and municipal construction, and a more effective rainwater outlet layout and urban infrastructure can be designed.

### BRIEF DESCRIPTION OF DRAWINGS

FIG. 1 illustrates a flowchart of a method for rapidly evaluating flood drainage effect based on machine learning and ensemble prediction according to an embodiment of the disclosure.

FIG. 2 illustrates a schematic diagram of constructing a data set based on a flood hydrodynamic numerical model according to an embodiment of the disclosure.

FIG. 3 illustrates a schematic diagram of a multi-regression model ensemble prediction method based on Bayesian optimization according to an embodiment of the disclosure.

### DETAILED DESCRIPTION OF EMBODIMENTS

A technical solution of the disclosure is further described in conjunction with drawings below.

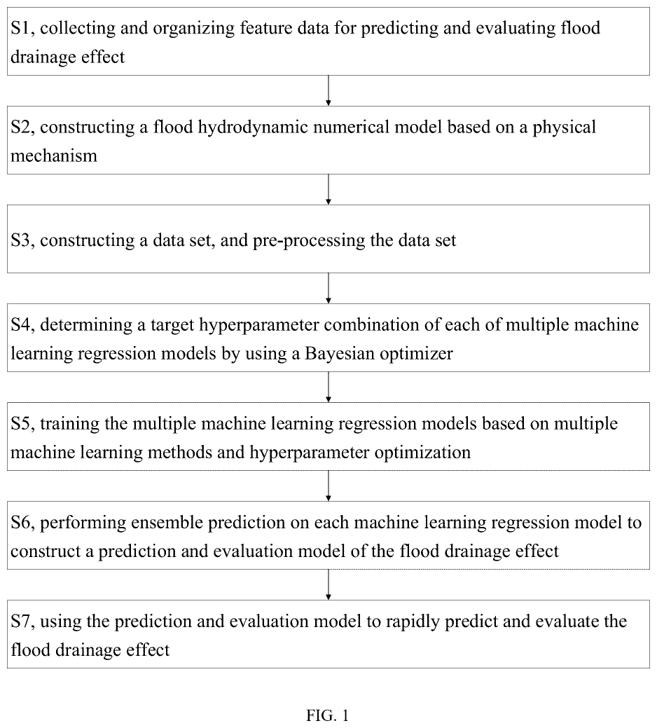

As shown in FIG. 1, an embodiment of the disclosure provides a method for rapidly evaluating flood drainage effect based on machine learning and ensemble prediction, including the following steps (1)-(8).

In step (1), data is collected. In order to study drainage effect of pipe network in different terrain features after heavy rainfall of different intensities and durations in urban environments, especially considering effects of surface water flow movement with terrain changes and slope changes on the drainage effect of the pipe network, it is necessary to collect relevant terrain data and rainfall data to drive simulation and calculation of a hydrodynamic model. In particular, terrain elevation data, different slope data, and rainfall data of different rainfall intensities and different rainfall durations are considered.

For the different slope data, in order to study the drainage effect of the pipeline network under the influence of different slopes, a series of analyzable slope conditions are created. A digital elevation model (DEM) of a selected research area is modified to change slope variation of the different slope data without affecting terrain characteristics of various urban buildings on earth's surface.

For the rainfall data of different rainfall intensities and different rainfall durations, a rainfall intensity formula is designed as follows:

$$i = ( A + C lg T ) / {( t + b )}^{n} ; \qquad ( 1 )$$

where i represents a designed rainstorm intensity; T represents a recurrence period, and t represents a rainfall duration; and A, C and b each represent a regional parameter, and n represents a rainstorm attenuation coefficient, and is also selected based on the selected research area like A, C and b.

In step (2), a flood hydrodynamic numerical model is constructed. The flood hydrodynamic numerical model driven by rainfall is calculated by using a two-dimensional shallow water equation, and a matrix form of a control equation of the two-dimensional shallow water equation is expressed as follows:

$$\frac{\partial q}{\partial t} + \frac{\partial f}{\partial x} + \frac{\partial g}{\partial y} = R + {S}_{b} + {S}_{f} ; \qquad ( 2 )$$

where t represents a time variable, x and y represent a Cartesian coordinate in horizontal and vertical directions, q represents a vector of each of hydraulic variables, f and g represent fluxes in an x direction and a y direction, respectively, R represents a mass term, S_{b} represents a bed slope, and S_{f} represents a bed friction term; and formulas of q, f, g, R, S_{b} and S_{f} are as follows:

$$q = {[ h , uh , vh ]}^{T} , f = {[ uh , {u}^{2} h + \frac{1}{2} {gh}^{2} , uvh ]}^{T} , \qquad ( 3 )$$

$$g = {[ vh , uvh , {v}^{2} h + \frac{1}{2} {gh}^{2} ]}^{T}$$

$$R = {[ R - I - D , 0 , 0 ]}^{T} , {S}_{b} = {[ 0 , - gh \frac{\partial b}{\partial x} , - gh \frac{\partial b}{\partial y} ]}^{T} ,$$

$${S}_{f} = {[ 0 , - {C}_{f} u \sqrt{{u}^{2} + {v}^{2}} , - {C}_{f} v \sqrt{{u}^{2} + {v}^{2}} ]}^{T} ;$$

where h represents a surface-water depth, u represents an average velocity component corresponding to the x direction, v represents an average velocity component corresponding to the y direction, b represents a bed elevation, g represents a gravitational acceleration, R represents a rainfall rate, I represents a penetration rate, D represents a drainage loss, and C_{f} represents a bed friction coefficient.

Based on the above control equation, a finite volume method in a Godunov format is used to perform spatial discretization on the control equation. A HLLC Riemann solver is used to calculate an interface flux, which can effectively capture shock waves and flood waves that propagate forward in a form of discontinuous waves. An explicit method is used to perform time discretization on the control equation; thus, the selection of a time step is crucial to ensure the stability and accuracy of the calculation of variables over time. Therefore, the time step is determined according to a CFL condition.

In step (3), the drainage loss is introduced into the flood hydrodynamic numerical model.

The disclosure mainly considers an impact of a layout of pipe network drainage outlets in municipal construction and a terrain slope on flooding, thus in the two-dimensional surface hydrodynamic numerical model, the rainwater outlet is mainly considered as a confluence point in the model. For the pipe network drainage loss in the step (2) (i.e., D in formula (3)), when a surface water flow rate is lower than a maximum carrying capacity of the rainwater outlet, a relationship between the surface drainage flow rate and the surface water after rainfall is considered, and the drainage loss is calculated using the following drainage relationship:

$$D = {c}_{0} \cdot {a}_{1} \cdot {h}^{{a}_{2}} ; \qquad ( 4 )$$

where a₁ and a₂ represent parameters related to a type of a rainwater outlet and corresponding geometric features of the rainwater outlet, h represents the surface-water depth, c₀ represents an efficiency coefficient of drainage on the rainwater outlet; and c₀ is used to indicate a situation where the rainwater outlet is blocked, with a value range of 0-1 (0 indicates complete blockage, and 1 indicates no blockage).

For the pipe network drainage loss in the step (2) (i.e., D in formula (3)), when the surface water flow rate is greater than the maximum carrying capacity of the rainwater outlet, the pipe network drainage loss in the model is the maximum carrying capacity of the rainwater outlet.

In step (4), a predicted value is defined. In order to quantify the pipe network drainage effects of different rainwater outlets under heavy rainfall, a normalized predicted value index R_{DE}, is defined. The R_{DE} index is expressed by calculating a relative difference in a flood inundation range before and after the pipe network drainage, and then normalizing it according to a total number of the rainwater outlets Nᵢₙₗₑₜ in the selected research area:

$${R}_{D E} = \frac{{A}_{noDL \vert {h}^{*}} - {A}_{DL \vert {h}^{*}}}{{N}_{inlet} \times {A}_{noDL \vert {h}^{*}}} ; \qquad ( 5 )$$

where A_{noDL} represents a flood inundation area without considering drainage under a water depth threshold h* (considering h*=0.1 m, h*=0.3 m, and h*=0.5 m) that affects a normal operation of pedestrians and vehicles in a city, and A_{DL} represents a flood inundation area considering the drainage under the water depth threshold h* that affects the normal operation of the pedestrians and vehicles in the city

Considering a density of the rainwater outlets in the selected research area, R_{DE} provides an overall quantification of the benefit index of rainwater outlet drainage in reducing a scope of local flood inundation. It focuses more on the drainage effect of rainwater outlets in the selected research area on the entire flood event, rather than the local effect of a single rainwater outlet. The higher the R_{DE} value, the more significant its drainage effect is in reducing ground water during the evolution of floods. By analyzing this indicator under different urban terrain characteristics and rainfall conditions, the effect of stormwater outlet layout on surface water drainage under the interaction of different terrain characteristics and rainfall characteristics can be quantified.

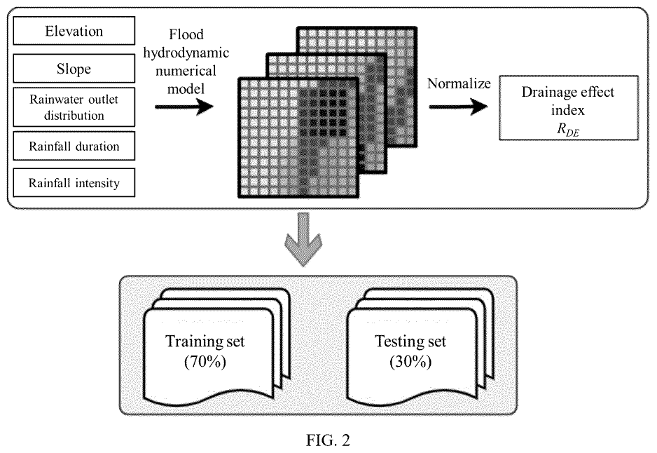

In step (5), as shown in FIG. 2, a data set is constructed. Different parameter combinations are taken as input parameters of the flood hydrodynamic numerical model, and the drainage effect index R_{DE} driven by each of the different parameter combinations are calculated based on the flood hydrodynamic numerical model. In order to reduce risk of overfitting and underfitting and improve the generalization ability of the model, the data set is divided into a training set and a testing set in a ratio of 7:3. At the same time, in order to improve the stability and efficiency of the model, all data needs to be normalized and preprocessed as follows:

$${X}_{n o r m} = \frac{X - {X}_{min}}{{X}_{max} - {X}_{min}} ; \qquad ( 6 )$$

where Xₙₒᵣₘ represents normalized data, X represents feature data to be processed, Xₘᵢₙ represents a minimum in X, and Xₘₐₓ represents a maximum in X.

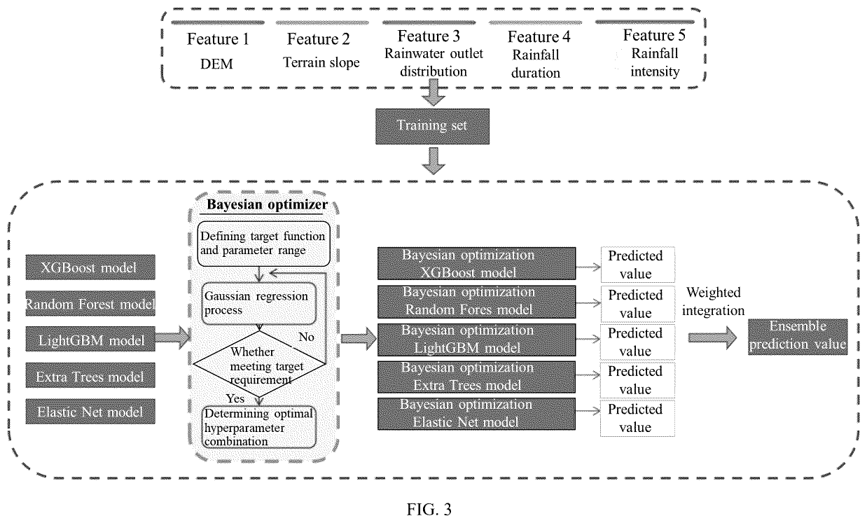

In step (6), as shown in FIG. 3, model hyperparameters are optimized. Multiple regression models based on machine learning methods and a method combing Bayesian hyperparameter optimization for ensemble prediction are used to construct multiple machine learning regression models to predict and evaluate the flood drainage effect, and ensemble prediction is performed. Five regression models based on machine learning methods are constructed and trained, including: an XGBoost model, a Random Forest model, a LightGBM model, an Extra Trees model and an Elastic Net model. The training steps of each model follow clear initialization parameters, model construction, feature selection, data splitting and integration logic to ensure that the drainage efficiency optimization problem can be effectively predicted.

The preprocessed data set is standardized to obtain a standardized training set and a standardized testing set. The standardized training set and the standardized testing set are used for training custom models, including the XGBoost, Random Forest, LightGBM, Extra Trees and Elastic Net models. For each model, a main parameter of the model is initialized to determine a value range of the main parameter, for example, a number of trees (n_estimators), a maximum depth (max_depth), a learning rate (learning_rate) and other hyperparameters, and an optimal value of each hyperparameter is determined by combining the Bayesian optimizer.

A Bayesian optimization process for the hyperparameters includes the follows. Firstly, a hyperparameter searching space is defined for each model, including the hyperparameters and the value range of each hyperparameter in the model. By defining the value range of each hyperparameter, it is ensured that the Bayesian optimizer can involve all possible hyperparameter combinations during the search process. After defining the value range of each hyperparameter, the Bayesian optimizer performs iterative search in the hyperparameter searching space. During each iteration, the Bayesian optimizer uses a Gaussian process to model an objective function based on current model performance results and a corresponding hyperparameter combination, predict a model performance of each model under different hyperparameter combinations, and calculate and select a next optimal hyperparameter combination (i.e., next target hyperparameter combination) based on an output of each model for experimentation. In each experimentation, for each hyperparameter combination, the Bayesian optimizer divides the data set into multiple subsets, sequentially uses the multiple subsets for training and validation, calculates an average error of each model, thereby evaluating a predictive performance of each model under the hyperparameter combination to obtain evaluation results. The Bayesian optimizer updates a searching strategy for the hyperparameter searching space based on the evaluation results, to maximize the search efficiency. In order to minimize training errors, the Bayesian optimizer aims to minimize a mean squared error (MSE) and iteratively processes the hyperparameter combinations of each model for multiple times, and ultimately outputs the optimal hyperparameter combination.

In step (7), the machine learning regression models are constructed and trained. After determining the optimal hyperparameter combination for each model, each model is trained.

(a) The XGBoost model initially predicts the training data, and calculates a residual between a predicted value and an actual value. During each iteration, the residual is input into a custom decision tree model for fitting to construct a new regression tree to learn the residual, predictive results of the XGBoost model are updated, and a final predicted value of the XGBoost model for the input data is obtained through the weighted sum of all weak learners.

(b) The Random Forest model generates multiple subsets from the standardized training data set through a self-sampling method, and each subset is used to train a custom decision tree model. The decision tree model gradually divides the data set starting from a root node until it reaches the maximum depth or meets conditions of a minimum sample split and a leaf node sample number. Each tree is trained on its training subset, and the prediction results of all trees are integrated and averaged to form a final predicted value of the Random Forest model for the input data.

(c) The LightGBM model inputs the training data into a LightGBM framework. The framework continuously improves the model performance by gradually constructing decision trees. In each iteration, the model selects a feature to split, determines an optimal split point by maximizing information gain, constructs a new tree to reduce the residual of the current model, and finally obtains a final predicted value of the LightGBM model for the input data by weighting the prediction results of all trees.

(d) The Extra Trees model randomly generates subsets from the standardized training data set through the self-sampling method, and each subset is used to train a custom decision tree model. Different from the Random Forest model, the Extra Trees model has stronger randomness when selecting feature split points, and the split point of each feature is completely randomly selected. The prediction results of all decision trees are integrated and averaged to obtain a final predicted value of the Extra Trees model for the input data.

(e) The Elastic Net model inputs the standardized training data into a regularized linear regression model. By minimizing the objective loss function, which includes a prediction error term and a regularization term. The model parameters are continuously updated by using a gradient descent method, and an optimal parameter configuration of the Elastic Net model is finally obtained and used to obtain a final predicted value of the Elastic Net model for the input data.

In step (8), the ensemble prediction is performed and the model is evaluated. After completing the training and optimization of each model, the prediction results of each model are combined for ensemble prediction. The advantages of different models under different data characteristics are used to reduce the possible errors of a single model, thereby improving the prediction accuracy. The process of the ensemble prediction is as follows.

For each testing sample, five models retrained after Bayesian optimization are used for prediction, including XGBoost, Random Forest, LightGBM, Extra Trees, and Elastic Net models. The predicted values generated by each model constitute a feature matrix containing the prediction results of all models, which is recorded as X_{ensemble} as follows:

$${X}_{e n s e m b l e} = [ {\hat{Y}}_{XGBoost} , {\hat{Y}}_{RandomForest} , {\hat{Y}}_{LightGBM} , {\hat{Y}}_{ExtraTrees} , {\hat{Y}}_{ElasticNet} ] ; \qquad ( 7 )$$

where Ŷ_{XGBoost} represents the final predicted value of the XGBoost model for the input data, Ŷ_{RandomForest} represents the final predicted value of the Random Forest model for the input data, Ŷ_{LightGBM} represents the final predicted value of the LightGBM model for the input data, Ŷ_{ExtraTrees} represents the final predicted value of the Extra Trees model for the input data, and Ŷ_{ElasticNet} represents the final predicted value of the Elastic Net model for the input data.

A linear weighted integration method is used to assign weights to the final predicted value of each model. The weights are weighted summed to obtain a final ensemble prediction value (i.e., the normalized predicted value index R_{DE}) and the prediction and evaluation model (i.e., a model integrating the XGBoost model, the Random Forest model, the LightGBM model, the Extra Trees model and the Elastic Net model). A least squares method is used to determine an optimal weight of each model.

A specifical process for determining the optimal weight of each model is as follows. A weight vector is assumed as w=[w_{XGBoost}, w_{RandomForest}, w_{LightGBM}, w_{ExtraTrees}, w_{ElasticNet}]. w_{XGBoost} represents a weight of the XGBoost model, w_{RandomForest} represents a weight of the Random Forest model, w_{LightGBM} represents a weight of the LightGBM model, w_{ExtraTrees} represents a weight of the Extra Trees model, and w_{ElasticNet} represents a weight of the Elastic Net model.

Thus, a final predicted value Ŷ_{ensemble} of each of testing samples is expressed as follows:

$${\hat{Y}}_{e n s e m b l e} = {w}_{XGBoost} \cdot {\hat{Y}}_{XGBoost} + {w}_{RandomForest} \cdot {\hat{Y}}_{RandomForest} + {w}_{LightGBM} \cdot {\hat{Y}}_{LightGBM} + {w}_{ExtraTrees} \cdot {\hat{Y}}_{ExtraTrees} + {w}_{ElasticNet} \cdot {\hat{Y}}_{ElasticNet} . \qquad ( 8 )$$

The feature matrix X_{ensemble} and an actual observation vector Yₜₑₛₜ of each testing sample are given, and an optimal weight vector (i.e., target weight vector) w* is determined through a minimize loss function (formula (9)) as follows:

$${{min}_{w} ( {X}_{ensemble} \cdot w - {Y}_{test} )}^{2} ; \qquad ( 9 )$$

After completing the ensemble prediction, a mean square error (MSE) and a R² score are used to evaluate the prediction and evaluation model. The expressions are as follows:

$$M S E = \frac{1}{n} {\sum }_{i = 1}^{n} {( {y}_{i} - {\hat{y}}_{i} )}^{2} ; \qquad ( 10 )$$

$${R}^{2} = 1 - \frac{{\sum }_{i = 1}^{n} {( {y}_{i} - {\hat{y}}_{ι} )}^{2}}{{\sum }_{i = 1}^{n} {( {y}_{i} - \overline{{y}_{i}} )}^{2}} ; \qquad ( 11 )$$

where MSE represents the mean square error, that is, an average of squares of the difference between the predicted value and the actual value, and is used to measure the prediction deviation of the model, the smaller the value, the smaller the error; R² represents a coefficient of determination, which measures an ability of the model to explain data fluctuations, the value range is 0 to 1, and the closer to 1, the better the model fit; n represents the number of samples used for verification; and yᵢ represents the predicted value, ŷᵢ represents the actual value, and y̅ᵢ̅ represents a sample mean.

By calculating MSE, the average error of the prediction and evaluation model on the test set can be evaluated. At the same time, the R² score can be used to measure the fit and explanatory power of the prediction and evaluation model for the data.

The disclosure provides an electronic device, including a memory, a processor and a computer program stored on the memory and executed on the processor, and the computer program is configured to be loaded on the processor to implement the method for rapidly evaluating the flood drainage effect based on machine learning and ensemble prediction.

The disclosure provides a non-transitory storage medium, the non-transitory storage medium is stored with a computer program, and the computer program is configured to be executed by the processor to implement the method for rapidly evaluating the flood drainage effect based on machine learning and ensemble prediction.

What is claimed is:

1. A method for evaluating flood drainage effect based on machine learning and ensemble prediction, comprising the following steps:
S1, collecting and organizing feature data for predicting and evaluating the flood drainage effect, specifically comprising:
collecting relevant terrain data and rainfall data to drive simulation and calculation of a hydrodynamic model, wherein the relevant terrain data comprises terrain elevation data and different slope data, the rainfall data is rainfall data of different rainfall intensities and different rainfall durations; for the different slope data, a digital elevation model of a selected research area is modified to change slope variation of the different slope data without affecting terrain characteristics of each urban building on earth's surface; and for the rainfall data of different rainfall intensities and different rainfall durations, a rainfall intensity formula is designed as follows:
$$i = ( A + C l g T ) / {( t + b )}^{n} ;$$
wherein i represents a designed rainstorm intensity; T represents a recurrence period, and t represents a rainfall duration; and A, C and b each represent a regional parameter, and n represents a rainstorm attenuation coefficient, and is selected based on the selected research area like A, C and b;
S2, constructing a flood hydrodynamic numerical model based on a physical mechanism, comprising:
calculating the flood hydrodynamic numerical model by using a two-dimensional shallow water equation, wherein a control equation of the two-dimensional shallow water equation is expressed as follows:
$$\frac{\partial q}{\partial t} + \frac{\partial f}{\partial x} + \frac{\partial g}{\partial y} = R + {S}_{b} + {S}_{f} ;$$
wherein t represents a time variable, x and y represent a Cartesian coordinate in horizontal and vertical directions, q represents a vector of each of hydraulic variables, f and g represent fluxes in an x direction and a y direction, respectively, R represents a mass term, S_{b} represents a bed slope, and S_{f} represents a bed friction term; and formulas of q, f, g, R, S_{b} and S_{f} are as follows:
$$q = {[ h , u h , v h ]}^{T} , \text{} f = {[ u h , {u}^{2} h + \frac{1}{2} g {h}^{2} , u v h ]}^{T} , \text{}$$
$$g = {[ vh , u v h , {v}^{2} h + \frac{1}{2} g {h}^{2} ]}^{T} \text{} R = {[ R - I - D , 0 , 0 ]}^{T} \text{} ,$$
$${S}_{b} = {[ 0 , - g h \frac{\partial b}{\partial x} , - g h \frac{\partial b}{\partial y} ]}^{T} , {S}_{f} = {[ 0 , - {C}_{f} u \sqrt{{u}^{2} + {v}^{2}} , - {C}_{f} v \sqrt{{u}^{2} + {v}^{2}} ]}^{T} ;$$
wherein h represents a surface-water depth, u represents an average velocity component corresponding to the x direction, v represents an average velocity component corresponding to the y direction, b represents a bed elevation, g represents a gravitational acceleration, R represents a rainfall rate, I represents a penetration rate, D represents a drainage loss, and C_{f} represents a bed friction coefficient; and
performing spatial discretization on the control equation by using a finite volume method in a Godunov format, calculating an interface flux by using a Harten-Lax-van Leer-contact (HLLC) Riemann solver, and performing time discretization on the control equation by using an explicit method, wherein a time step is determined according to a Courant-Friedrichs-Lewy (CFL) condition; and a formula of the drainage loss D is expressed as follows:
$$D = {c}_{0} \cdot a \cdot {h}^{b} ;$$
wherein a and b represent parameters related to a type of a rainwater outlet and corresponding geometric features of the rainwater outlet, c₀ represents an efficiency coefficient of drainage on the rainwater outlet; and c₀ is used to indicate a situation where the rainwater outlet is blocked, with a value range of 0-1, 0 indicates complete blockage, and 1 indicates no blockage;
S3, constructing a data set, and pre-processing the data set, specifically comprising:
defining a normalized predicted value index R_{DE}, wherein a formula of the normalized predicted value index R_{DE} is expressed as follows:
$${R}_{D E} = \frac{{A}_{noDL \vert {h}^{*}} - {A}_{D L \vert {h}^{*}}}{{N}_{inlet} \times {A}_{n o D L \vert {h}^{*}}} ;$$
wherein A_{noDL} represents a flood inundation area without considering drainage under a water depth threshold h* that affects a normal operation of pedestrians and vehicles in a city, and A_{DL} represents a flood inundation area considering the drainage under the water depth threshold h* that affects the normal operation of the pedestrians and vehicles in the city; and Nᵢₙₗₑₜ represents a total number of rainwater outlets in the selected research area;
taking different parameter combinations as input parameters of the flood hydrodynamic numerical model, and calculating, based on the flood hydrodynamic numerical model, the drainage effect index R_{DE} driven by each of the different parameter combinations to construct the data set; and
dividing the data set into a training set and a testing set, and performing normalization preprocessing on the training set and the testing set;
S4, determining a target hyperparameter combination of each of a plurality of machine learning regression models by using a Bayesian optimizer, specifically comprising:
constructing, by using a plurality of machine learning methods and combining the Bayesian optimizer, the plurality of machine learning regression models to predict and evaluate the flood drainage effect of urbans, wherein the plurality of machine learning regression models comprise: an extreme gradient boosting (XGBoost) model, a Random Forest model, a light gradient boosting machine (LightGBM) model, an extremely randomized tree (Extra Trees) model, and an elastic network (Elastic Net) model;
for each of the plurality of machine learning regression models, initializing hyperparameters to determine a value range of each of the hyperparameters, and determining a target value of each of the hyperparameters by combining the Bayesian optimizer, wherein the hyperparameters comprise: a number of trees (n_estimators), a maximum depth (max_depth) and a learning rate (learning_rate);
performing Bayesian optimization on the hyperparameters, comprising:
defining a hyperparameter searching space for each of the plurality of machine learning regression models, wherein the hyperparameter searching space comprises the hyperparameters and the value range of each of the hyperparameters; wherein the value range of each of the hyperparameters is defined to ensure that the Bayesian optimizer involves all possible hyperparameter combinations during a searching process;
performing, by the Bayesian optimizer, iterative search in the hyperparameter searching space after defining the value range of each of the hyperparameters, wherein, during each iteration, the Bayesian optimizer uses a Gaussian process to model an objective function based on current model performance results and a corresponding hyperparameter combination, predict a performance of each of the plurality of machine learning regression models under different hyperparameter combinations, and calculate and select a next target hyperparameter combination based on an output of each of the plurality of machine learning regression models for experimentation; in each experimentation, for each of the hyperparameter combinations, the Bayesian optimizer divides the data set into a plurality of subsets, sequentially uses the plurality of subsets for training and validation, calculates an average error of each of the plurality of machine learning regression models, to thereby evaluate a predictive performance of each of the plurality of machine learning regression models under the hyperparameter combination to obtain evaluation results; the Bayesian optimizer updates a searching strategy for the hyperparameter searching space based on the evaluation results; and the Bayesian optimizer aims to minimize a mean squared error (MSE) and iteratively processes the hyperparameter combinations of each of the plurality of machine learning regression models for a plurality of times, and ultimately outputs the target hyperparameter combination;
S5, training each of the plurality of machine learning regression models based on the plurality of machine learning methods and hyperparameter optimization, specifically comprising:
training each of the plurality of machine learning regression models after determining the target hyperparameter combination for each of the plurality of machine learning regression models, comprising:
training the XGBoost model to obtain a final predicted value of the XGBoost model for input data;
training the Random Forest model to obtain a final predicted value of the Random Forest model for the input data;
training, by weighting predictive results of all trees, the LightGBM model to obtain a final predicted value of the LightGBM model for the input data;
training the Extra Trees model to obtain a final predicted value of the Extra Trees model for the input data; and
training the Elastic Net model to obtain a target parameter configuration of the Elastic Net model to thereby obtain a final predicted value of the Elastic Net model for the input data;
S6, performing ensemble prediction on each of the plurality of machine learning regression models to construct a prediction and evaluation model of the flood drainage effect, specifically comprising:
recording a feature matrix containing predictive results of the plurality of machine learning regression models formed by the final predicted value of the XGBoost model, the final predicted value of the Random Forest model, the final predicted value of the LightGBM model, the final predicted value of the Extra Trees model and the final predicted value of the Elastic Net model for the input data as X_{ensemble}, wherein the feature matrix X_{ensemble} is expressed as follows:
$${X}_{e n s e m b l e} = [ {\hat{Y}}_{XGBoost} , {\hat{Y}}_{RandomForest} , {\hat{Y}}_{LightGBM} , {\hat{Y}}_{ExtraTrees} , {\hat{Y}}_{ElasticNet} ] ;$$
wherein Ŷ_{XGBoost} represents the final predicted value of the XGBoost model for the input data, Ŷ_{RandomForest} represents the final predicted value of the Random Forest model for the input data, Ŷ_{LightGBM} represents the final predicted value of the LightGBM model for the input data, Ŷ_{ExtraTrees} represents the final predicted value of the Extra Trees model for the input data, and Ŷ_{ElasticNet} represents the final predicted value of the Elastic Net model for the input data;
assigning, by using a linear weighted integration method, weights to the final predicted value of the XGBoost model, the final predicted value of the Random Forest model, the final predicted value of the LightGBM model, the final predicted value of the Extra Trees model and the final predicted value of the Elastic Net model to perform weighted sum, to thereby a final ensemble prediction value, comprising:
determining a target weight of each of the XGBoost model, the Random Forest model, the LightGBM model, the Extra Trees model and the Elastic Net model by using a least squares method, comprising:
assuming a weight vector as w=[w_{XGBoost}, w_{RandomForest}, w_{LightGBM}, w_{ExtraTrees}, w_{ElasticNet}], wherein w_{XGBoost} represents a weight of the XGBoost model, w_{RandomForest} represents a weight of the Random Forest model, w_{LightGBM} represents a weight of the LightGBM model, w_{ExtraTrees} represents a weight of the Extra Trees model, and w_{ElasticNet} represents a weight of the Elastic Net model; and a final predicted value Ŷ_{ensemble} of each of testing samples is expressed as follows:
$${\hat{Y}}_{e n s e m b l e} = {w}_{XGBoost} \cdot {\hat{Y}}_{XGBoost} + {w}_{RandomForest} \cdot {\hat{Y}}_{RandomForest} + {w}_{LightGBM} \cdot {\hat{Y}}_{LightGBM} + {w}_{ExtraTrees} \cdot {\hat{Y}}_{ExtraTrees} + {w}_{ElasticNet} \cdot {\hat{Y}}_{ElasticNet} ;$$
determining a target weight vector w* through a minimize loss function and using the feature matrix X_{ensemble} and an actual observation value vector Yₜₑₛₜ of each of the testing samples, wherein a formula of the minimize loss function is expressed as follows:
$${{min}_{w} ( {X}_{ensemble} \cdot w - {Y}_{test} )}^{2} ;$$
performing, by using the target weight of each of the XGBoost model, the Random Forest model, the LightGBM model, the Extra Trees model and the Elastic Net model, the weighted sum on the final predicted value of the XGBoost model, the final predicted value of the Random Forest model, the final predicted value of the LightGBM model, the final predicted value of the Extra Trees model and the final predicted value of the Elastic Net model to obtain the final ensemble prediction value and the prediction and evaluation model; and
evaluating the prediction and evaluation model by using a mean square error and a R-squared (R²) score after completing the ensemble prediction; and
S7, using the prediction and evaluation model of the step S6 to evaluate and predict the flood drainage effect.

2. An electronic device, comprising a memory, a processor and a computer program stored on the memory and executed on the processor, wherein the computer program is configured to be loaded on the processor to implement the method for evaluating the flood drainage effect based on machine learning and ensemble prediction as claimed in claim 1.

3. A storage medium, stored with a computer program, wherein the computer program is configured to be executed by a processor to implement the method for evaluating the flood drainage effect based on machine learning and ensemble prediction as claimed in claim 1.
